(19) United States
(12) Patent Application Publication
(10) Pub. No.: US 2026/0052949 A1
(43) Pub. Date: Feb. 19, 2026

(54) SEMICONDUCTOR DEVICE MANUFACTURING METHOD

(71) Applicants: Kabushiki Kaisha Toshiba, Kawasaki-shi (JP); Toshiba Electronic Devices & Storage Corporation, Kawasaki-shi (JP)

(72) Inventors: Kentaro MORI, Fujisawa Kanagawa (JP); Kenichi OOHASHI, Kawasaki Kanagawa (JP); Kazushiro NOMURA, Kawasaki Kanagawa (JP); Yuma YAMASHITA, Yokohama Kanagawa (JP)

(21) Appl. No.: 19/368,368

(22) Filed: Oct. 24, 2025

Related U.S. Application Data
(63) Continuation of application No. PCT/JP2024/006769, filed on Feb. 26, 2024.

(30) Foreign Application Priority Data
Jul. 31, 2023 (JP) 2023-124444

(51) Int. Cl. H01L 21/683; H01L 21/304; H01L 21/67

(52) U.S. Cl. CPC H01L 21/6835; H01L 21/304; H01L 21/6715; H01L 2221/68327

(57) ABSTRACT

A semiconductor device manufacturing method of manufacturing a semiconductor device by machining a substrate including a first surface and a second surface opposite to the first surface is provided. The semiconductor device manufacturing method including: forming a first trimmed part by performing trimming of the substrate from the first surface side; forming a second trimmed part by performing trimming of the substrate from the first surface side; forming an adhesive layer on the first surface using a spin coating method including rotating the substrate around a rotation axis; fixing the substrate to a support member via the adhesive layer; and grinding the substrate from the second surface side to decrease a dimension in a thickness direction of the substrate. The second trimmed part includes a part which is located on an inner side with respect to the first trimmed part in a radial direction from the rotation axis.

### CROSS-REFERENCE TO RELATED APPLICATION

This application is based upon and claims the benefit of priority from Japanese Patent Application No. 2023-124444, filed on Jul. 31, 2023; the entire contents of which are incorporated herein by reference.

### FIELD

Embodiments described herein relate generally to a semiconductor device manufacturing method.

### BACKGROUND

A semiconductor device that is manufactured by machining a substrate (a wafer) is known. In manufacturing such a semiconductor device, a substrate may be fixed to a support member by an adhesive, and the substrate may be ground to be thinner. In this case, at the time of fixing the substrate to the support member using an adhesive, the adhesive may turn and flow to a side surface of the substrate. When the adhesive turns and flows to the side surface of the substrate, the adhesive attached to the side surface of the substrate may be separated at the time of grinding the substrate, and there is a problem in that the separated adhesive may be attached to a surface of the ground substrate. Accordingly, a step of removing the separated adhesive needs to be provided after the step of grinding the substrate, and thus there is a problem in that the number of steps of manufacturing a semiconductor device increases.

### BRIEF DESCRIPTION OF THE DRAWINGS

FIG. 1 is a sectional view illustrating a semiconductor device according to a first embodiment.

FIG. 2 is a flowchart illustrating a method of manufacturing the semiconductor device according to the first embodiment.

FIG. 3 is a plan view illustrating a wafer according to the first embodiment.

FIG. 4 is a sectional view illustrating a first trimming step according to the first embodiment.

FIG. 5 is a plan view illustrating a wafer on which the first trimming step and a second trimming step according to the first embodiment have been performed.

FIG. 6 is a sectional view illustrating a part of a wafer on which the first trimming step and the second trimming step according to the first embodiment have been performed.

FIG. 7 is a sectional view illustrating an adhesive layer forming step according to the first embodiment.

FIG. 8 is a sectional view illustrating a part of a wafer on which the adhesive layer forming step according to the first embodiment has been performed.

FIG. 9 is a sectional view illustrating a part of a wafer on which a support member fixing step according to the first embodiment has been performed.

FIG. 10 is a sectional view illustrating a part of a wafer on which a grinding step according to the first embodiment has been performed.

FIG. 11 is a sectional view illustrating a part of a wafer on which a metal film forming step according to the first embodiment has been performed.

FIG. 12 is a plan view illustrating a wafer on which a first trimming step and a second trimming step according to a second embodiment have been performed.

FIG. 13 is a sectional view illustrating a part of a wafer on which the first trimming step and the second trimming step according to the second embodiment have been performed.

FIG. 14 is a sectional view illustrating a part of a wafer on which a first trimming step and a second trimming step according to a third embodiment have been performed.

### DETAILED DESCRIPTION

A method of manufacturing a semiconductor device according to an embodiment is a semiconductor device manufacturing method of manufacturing a semiconductor device by machining a substrate including a first surface on which a circuit part is provided and a second surface opposite to the first surface. The semiconductor device manufacturing method according to the embodiment includes forming a first trimmed part by performing trimming of the substrate from the first surface side, forming a second trimmed part by performing trimming of the substrate from the first surface side, forming an adhesive layer on the first surface using a spin coating method including rotating the substrate around a rotation axis, fixing the substrate to a support member via the adhesive layer, and grinding the substrate from the second surface side to decrease a dimension in a thickness direction of the substrate. The second trimmed part includes a part which is located on an inner side with respect to the first trimmed part in a radial direction from the rotation axis.

Hereinafter, a semiconductor device manufacturing method according to embodiments will be described with reference to the accompanying drawings.

### First Embodiment

FIG. 1 is a sectional view illustrating a semiconductor device 100 that is manufactured using a semiconductor device manufacturing method according to a first embodiment. As illustrated in FIG. 1, a semiconductor device 100 includes a substrate part 10, a circuit part 11 that is formed on one surface of the substrate part 10, and a metal film 12 that is formed on the other surface of the substrate part 10. The substrate part 10 is a plate-shaped part that is formed by dicing a wafer (substrate) 20 which will be described later. A material of the substrate part 10 is a semiconductor material. The material of the substrate part 10 is, for example, silicon (Si), silicon carbide (SiC), or gallium nitride (GaN). The circuit part 11 is a part in which a circuit pattern is formed. Although not illustrated, the circuit part 11 includes, for example, an electrode part. The metal film 12 is formed on the whole other surface of the substrate part 10. A material of the metal film 12 is, for example, a material including one or more of titanium (Ti), nickel (Ni), gold (Au), silver (Ag), and copper (Cu). The metal film 12 is, for example, a Ti/Ni/Au stacked film or a Ti/Ni/Ag stacked film.

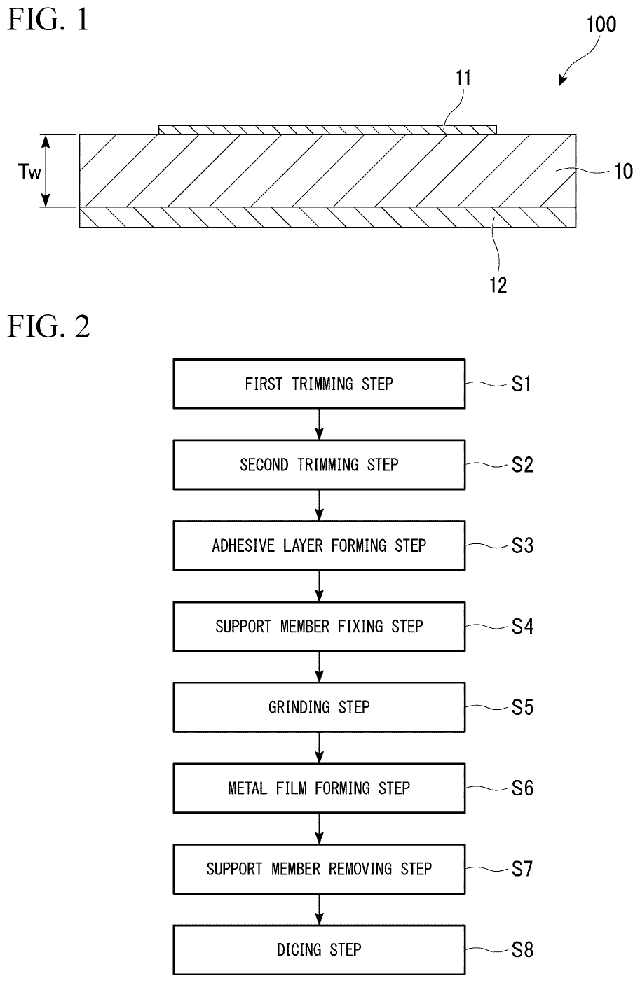

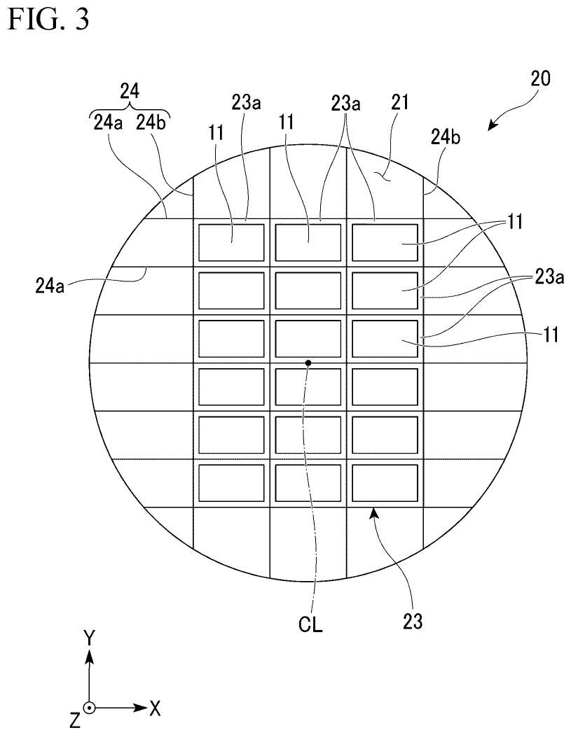

FIG. 2 is a flowchart illustrating a method of manufacturing the semiconductor device 100 according to the first embodiment. FIG. 3 is a plan view illustrating a wafer 20 that is used to manufacture the semiconductor device 100. The method of manufacturing the semiconductor device 100 is a method of manufacturing the semiconductor device 100 by machining the wafer 20. As illustrated in FIG. 2, the method of manufacturing the semiconductor device 100 includes a first trimming step S1, a second trimming step S2, an adhesive layer forming step S3, a support member fixing step S4, a grinding step S5, a metal film forming step S6, a support member removing step S7, and a dicing step S8.

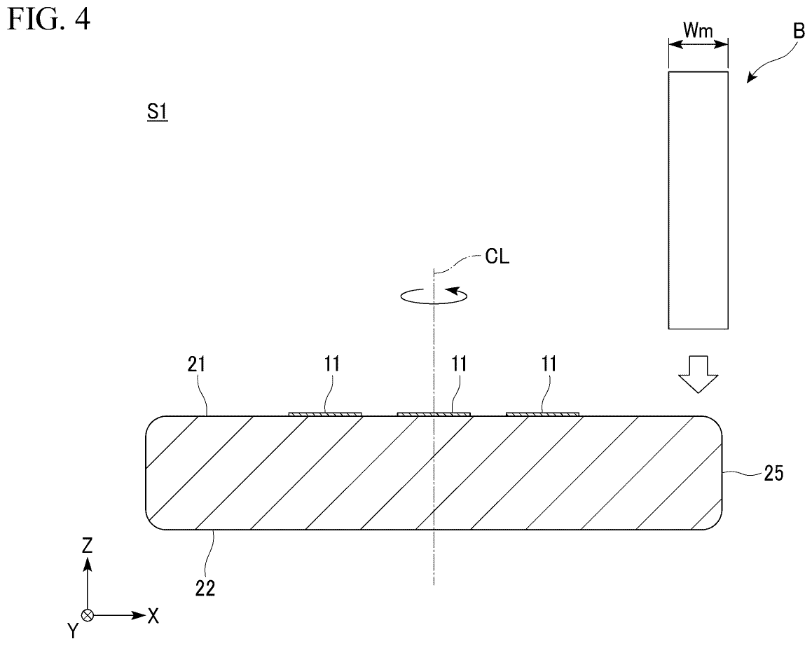

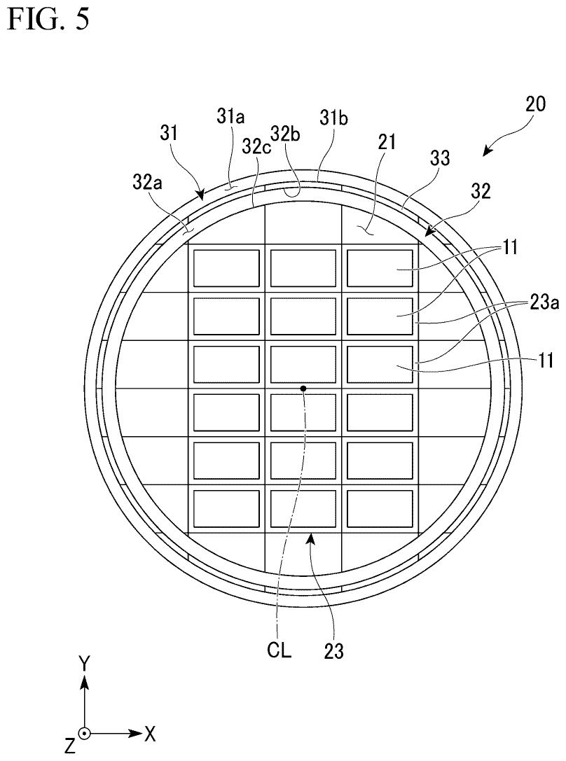

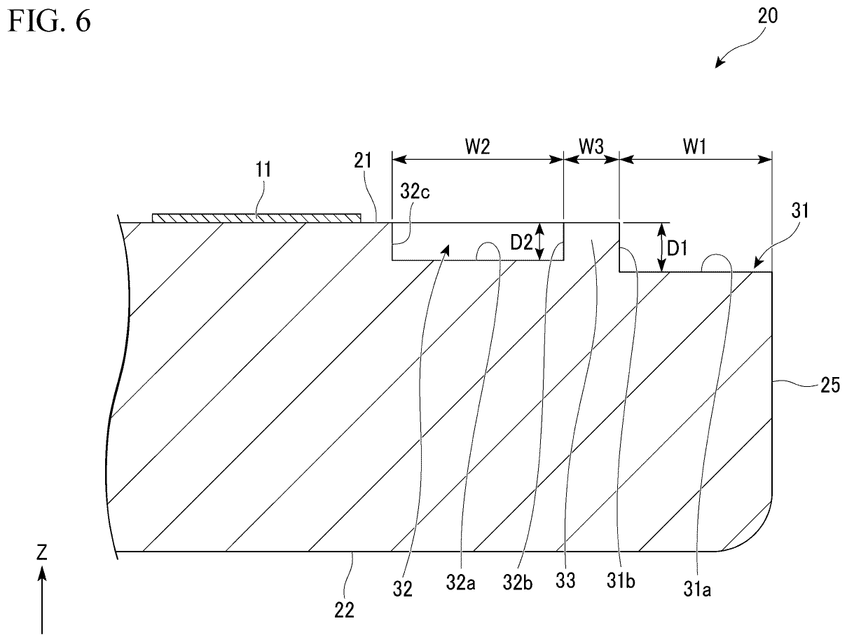

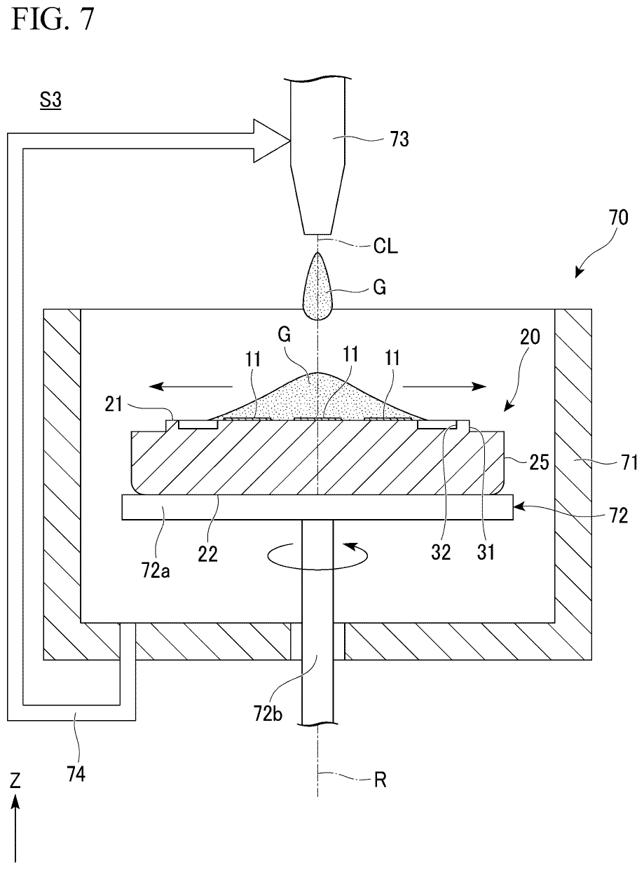

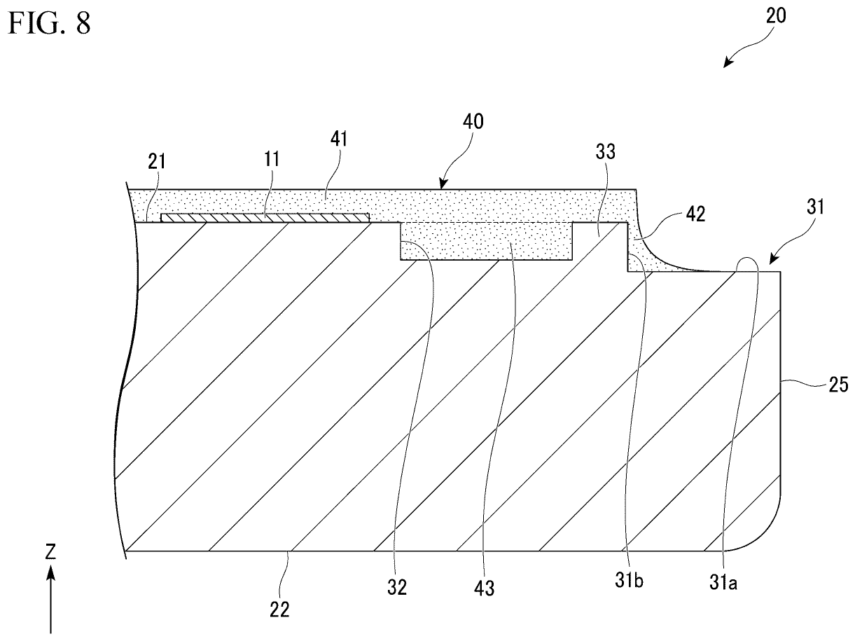

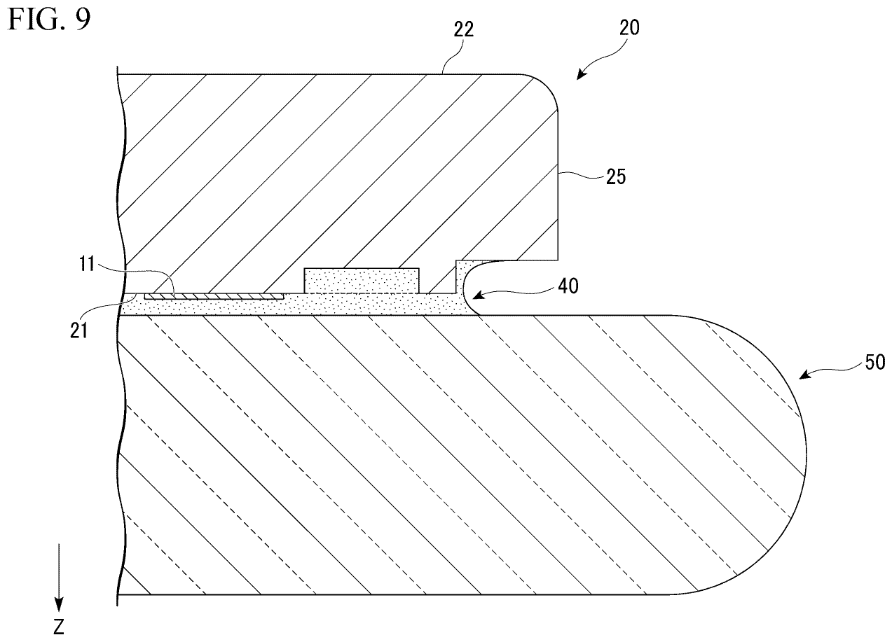

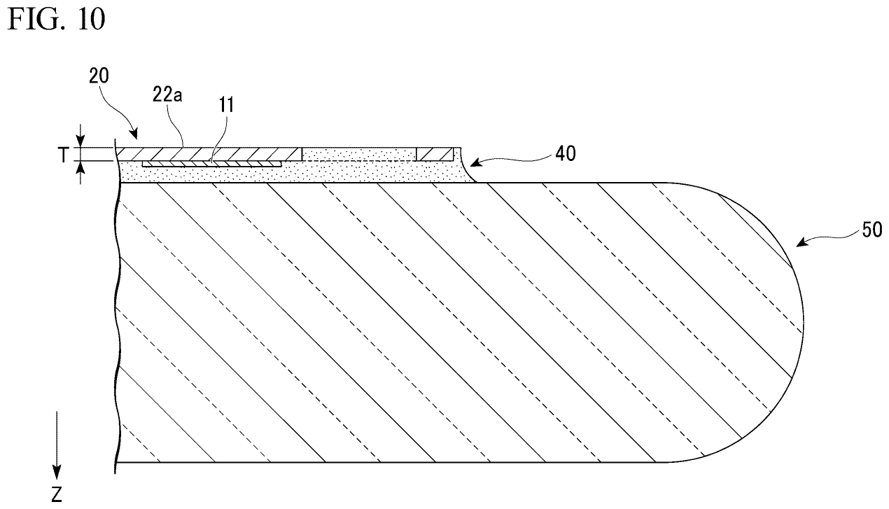

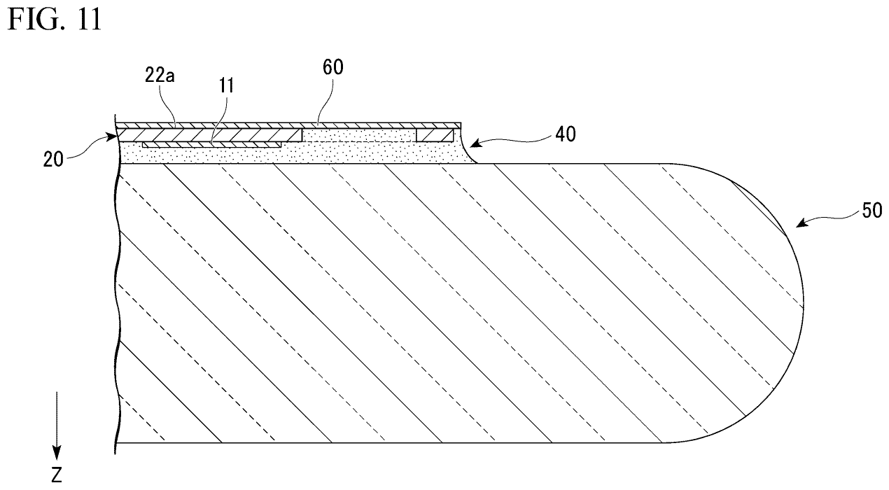

FIG. 4 is a sectional view illustrating the first trimming step S1. FIG. 5 is a plan view illustrating a wafer 20 on which the first trimming step S1 and the second trimming step S2 have been performed. FIG. 6 is a sectional view illustrating a part of the wafer 20 on which the first trimming step S1 and the second trimming step S2 have been performed. FIG. 7 is a sectional view illustrating the adhesive layer forming step S3. FIG. 8 is a sectional view illustrating a part of the wafer 20 on which the adhesive layer forming step S3 has been performed. FIG. 9 is a sectional view illustrating a part of the wafer 20 on which the support member fixing step S4 has been performed. FIG. 10 is a sectional view illustrating a part of the wafer 20 on which the grinding step S5 has been performed. FIG. 11 is a sectional view illustrating a part of the wafer 20 on which the metal film forming step S6 has been performed.

As illustrated in FIGS. 3 and 4, the wafer 20 that is used to manufacture a semiconductor device 100 has a disc shape. In the drawings, appropriately, a thickness direction of the wafer 20 is defined as a Z-axis direction, one direction perpendicular to the thickness direction of the wafer 20 is defined as an X-axis direction, and a direction perpendicular to both the Z-axis direction and the X-axis direction is defined as a Y-axis direction. The X-axis direction is a left-right direction in FIG. 3. The Y-axis direction is an up-down direction in FIG. 3. In the following description, the X-axis direction is referred to as a “first direction X,” the Y-axis direction is referred to as a “second direction Y,” and the Z-axis direction is referred to as a “thickness direction Z.” The wafer 20 in the first embodiment corresponds to a “substrate.”

As illustrated in FIG. 4, the wafer 20 includes a first surface 21 and a second surface 22. The first surface 21 is one plate surface of the wafer 20. The second surface 22 is the other plate surface of the wafer 20, that is, a surface opposite to the first surface 21. The first surface 21 is a device surface on which the circuit part 11 is provided. A plurality of circuit parts 11 are formed on the first surface 21. As illustrated in FIG. 3, a plurality of circuit parts 11 are arranged in a matrix shape in which they are arranged in the first direction X and the second direction Y.

A plurality of dicing lines 24 are formed on the first surface 21. The dicing lines 24 include a first dicing line 24a extending in the first direction X and a second dicing line 24b extending in the second direction Y. A plurality of first dicing lines 24a are formed at intervals in the second direction Y. A plurality of second dicing lines 24b are formed at intervals in the first direction X. Each first dicing line 24a crosses the plurality of second dicing lines 24b. Each second dicing line 24b crosses the plurality of first dicing lines 24a. An area surrounded by a pair of first dicing lines 24a adjacent to each other in the second direction Y and a pair of second dicing lines 24b adjacent to each other in the first direction X is a dicing area 23a which is diced in the dicing step S8. A plurality of dicing areas 23a are arranged in a matrix shape in which they are arranged in the first direction X and the second direction Y. The device area 23 includes a plurality of dicing areas 23a.

In the following description, a side in the thickness direction Z on which the first surface 21 is located with respect to the second surface 22, that is, a side (a +Z side) to which an arrow of the Z axis is directed, is referred to as a “first side,” and a side in the thickness direction Z on which the second surface 22 is located with respect to the first surface 21, that is, a side (a −Z side) opposite to the side to which the arrow of the Z axis is directed, is referred to as a “second side.”

The first trimming step S1 is a step of forming a first trimmed part 31 by performing trimming of the wafer 20 from the first surface 21 side. As illustrated in FIG. 4, in the first trimming step S1 according to the first embodiment, a part of a wafer 20 is cut using a blade B. In the first trimming step S1, a part of the wafer 20 is cut, for example, by bringing the blade B into contact with an outer circumferential edge of the first surface 21 of the wafer 20 and rotating the wafer 20 around a center axis CL. The center axis CL is a virtual line passing through the center of the wafer 20 of a disk shape and extending in the thickness direction Z. In the following description, a radial direction from the center axis CL may be simply referred to as a “radial direction.”

“Performing trimming of a certain object” in this specification means that a part of the certain object is removed, and how to remove a part of the certain object is not particularly limited. That is, “performing trimming of a wafer 20” means that a part of the wafer 20 is removed, and a part of the wafer 20 may be removed by cutting or a part of the wafer 20 may be removed by etching or the like. “A trimmed part formed by performing trimming of a certain object” means a part which is formed by removing a part of the certain object.

As illustrated in FIG. 5, a first trimmed part 31 is formed through the first trimming step S1. The first trimmed part 31 in the first embodiment is formed all over an outer circumferential edge of the first surface 21. The first trimmed part 31 has a ring shape centered on the center axis CL. As illustrated in FIG. 6, a stepped portion which is recessed to the second surface 22 side (the −Z side) is formed in the outer circumferential edge of the wafer 20 by the first trimmed part 31. The first trimmed part 31 includes a bottom surface 31a and a side surface 31b. The bottom surface 31a is a surface facing the first side (the +Z side) and having a ring shape perpendicular to the thickness direction Z. An outer end in the radial direction of the bottom surface 31a is connected to a side surface 25 of the wafer 20. The side surface 25 of the wafer 20 is an outer surface in the radial direction of the wafer 20. By forming the first trimmed part 31, an end portion on the first side of the side surface 25 of the wafer 20 is removed. The side surface 31b is a surface facing outward in the radial direction and having a ring shape. An end portion on the second side (the −Z side) of the side surface 31b is connected to an inner end in the radial direction of the bottom surface 31a.

A width W1 in the radial direction of the first trimmed part 31 is equal to or less than a width Wm in the radial direction of the blade B. The width W1 in the radial direction of the first trimmed part 31 in the first embodiment is less than the width Wm in the radial direction of the blade B. The width W1 in the radial direction of the first trimmed part 31 is the same as a width in the radial direction of the bottom surface 31a. A dimension D1 in the thickness direction Z of the first trimmed part 31 is greater than a dimension Tw in the thickness direction Z of the substrate part 10 in the semiconductor device 100. The dimension D1 in the thickness direction Z of the first trimmed part 31 is, for example, equal to or greater than two times the dimension Tw in the thickness direction Z of the substrate part 10 and about equal to or less than four times the dimension Tw. The dimension D1 in the thickness direction Z of the first trimmed part 31 is the same as a dimension in the thickness direction Z of the side surface 31b. The width W1 in the radial direction of the first trimmed part 31 is not particularly limited and is, for example, equal to or greater than 200 μm and equal to or less than about 700 μm. The dimension D1 in the thickness direction Z of the first trimmed part 31 is not particularly limited and is, for example, equal to or greater than 100 μm and equal to or less than about 200 82 m when the dimension Tw in the thickness direction Z of the substrate part 10 is about 50 μm. The dimension Tw in the thickness direction Z of the substrate part 10 is not particularly limited and is, for example, equal to or greater than 10 μm and equal to or less than about 100 μm.

The second trimming step S2 is a step of forming a second trimmed part 32 by performing trimming of the wafer 20 from the first surface 21 side. In the second trimming step S2 according to the first embodiment, the second trimmed part 32 is formed by cutting a part of the wafer 20 using the same blade B as the blade B used in the first trimming step S1. As illustrated in FIG. 5, the second trimmed part 32 in the first embodiment is a ring-shaped groove. More specifically, the second trimmed part 32 is a ring-shaped groove centered on the center axis CL. The second trimmed part 32 is separated inward in the radial direction from the first trimmed part 31. An outer diameter of the second trimmed part 32 is less than an inner diameter of the first trimmed part 31.

As illustrated in FIG. 6, the second trimmed part 32 includes a groove bottom surface 32a and a pair of inner side surfaces 32b and 32c. The groove bottom surface 32a faces the first side (the +Z side) and is a ring-shaped surface perpendicular to the thickness direction Z. The groove bottom surface 32a is located on the first side with respect to the bottom surface 31a of the first trimmed part 31. The inner side surface 32b is a ring-shaped surface facing inward in the radial direction. The inner side surface 32c is a ring-shaped surface facing outward in the radial direction. The pair of inner side surfaces 32b and 32c face each other with a gap in the radial direction. An end on the second side (the −Z side) of the inner side surface 32b is connected to an outer end in the radial direction of the groove bottom surface 32a. An end on the second side of the inner side surface 32c is connected to an inner end in the radial direction of the groove bottom surface 32a.

In the first embodiment, a width W2 in the radial direction of the second trimmed part 32 is equal to or greater than the width W1 in the radial direction of the first trimmed part 31. More specifically, the width W2 in the radial direction of the second trimmed part 32 is greater than the width W1 in the radial direction of the first trimmed part 31. In the first embodiment, the width W2 in the radial direction of the second trimmed part 32 is equal to a width Wm in the radial direction of the blade B. The width W2 in the radial direction of the second trimmed part 32 is equal to the width in the radial direction of the groove bottom surface 32a. The width W2 in the radial direction of the second trimmed part 32 is not particularly limited and is, for example, equal to or greater than 200 μm and equal to or less than about 700 μm.

In the first embodiment, a dimension D2 in the thickness direction Z of the second trimmed part 32 is less than the dimension D1 in the thickness direction Z of the first trimmed part 31. The dimension D2 in the thickness direction Z of the second trimmed part 32 is equal to a dimension in the thickness direction Z of the inner side surfaces 32b and 32c. The dimension D2 in the thickness direction Z of the second trimmed part 32 is greater than the dimension Tw in the thickness direction Z of the substrate part 10 in the semiconductor device 100. The dimension D2 in the thickness direction Z of the second trimmed part 32 is, for example, equal to or greater than two times the dimension Tw in the thickness direction Z of the substrate part 10 and equal to or less than about four times the dimension Tw. The dimension D2 in the thickness direction Z of the second trimmed part 32 is not particularly limited and is, for example, equal to or greater than 100 μm and equal to or less than about 200 μm.

By forming the first trimmed part 31 and the second trimmed part 32, a protruding part 33 protruding to the first side (the +Z side) is formed between the first trimmed part 31 and the second trimmed part 32 in the radial direction. The protruding part 33 is a part which is located between the first trimmed part 31 and the second trimmed part 32 in the radial direction. As illustrated in FIG. 5, the protruding part 33 in the first embodiment has a ring shape centered on the center axis CL. As illustrated in FIG. 6, a width W3 in the radial direction of the protruding part 33 is less than the width W1 in the radial direction of the first trimmed part 31 and the width W2 in the radial direction of the second trimmed part 32. The width W3 in the radial direction of the protruding part 33 is greater than at least one of the dimension D1 in the thickness direction Z of the first trimmed part 31 and the dimension D2 in the thickness direction Z of the second trimmed part 32. In the first embodiment, the width W3 in the radial direction of the protruding part 33 is greater than both of the dimension D1 in the thickness direction Z of the first trimmed part 31 and the dimension D2 in the thickness direction Z of the second trimmed part 32. The width W3 in the radial direction of the protruding part 33 is not particularly limited and is, for example, equal to or greater than 50 μm and equal to or less than about 300 μm.

The adhesive layer forming step S3 is a step of forming an adhesive layer 40 on the first surface 21 of the wafer 20 using a spin coating method including rotating the wafer 20 around a rotation axis R. As illustrated in FIG. 7, in the adhesive layer forming step S3 according to the first embodiment, the adhesive layer 40 is formed using a spin coater 70. The spin coater 70 includes an accommodation unit 71, a mount unit 72, a nozzle unit 73, and a recovery unit 74.

The accommodation unit 71 accommodates the wafer 20 therein. The accommodation unit 71 has a container shape which is open upward in the vertical direction. The wafer 20 is mounted on the mount unit 72. The mount unit 72 can rotate around the rotation axis R. The rotation axis R is a virtual axis extending in the vertical direction. The rotation axis R matches the center axis CL of the wafer 20 mounted on the mount unit 72. That is, in the adhesive layer forming step S3, the radial direction centered on the rotation axis R is the radial direction centered on the center axis CL. The mount unit 72 includes a mount body 72a having a disc shape on which the wafer 20 is mounted and a shaft part 72b extending downward in the vertical direction from the mount body 72a. The mount body 72a is located in the accommodation unit 71. The shaft part 72b extends through the bottom of the accommodation unit 71. Although not illustrated. A drive unit such as a motor is connected to the shaft part 72b. The mount unit 72 is rotated around the rotation axis R by the drive unit.

The nozzle unit 73 supplies an adhesive G for forming the adhesive layer 40 onto the wafer 20. The nozzle unit 73 is separated upward in the vertical direction from the mount unit 72. The recovery unit 74 recovers the adhesive G from the inside of the accommodation unit 71 to the nozzle unit 73.

In the adhesive layer forming step S3, an uncured adhesive G is supplied from the nozzle unit 73 onto the wafer 20 mounted on the mount unit 72. The wafer 20 is mounted on the mount unit 72 in a state in which the first surface 21 faces upward in the vertical direction. Accordingly, the adhesive G supplied from the nozzle unit 73 is supplied onto the first surface 21. In the adhesive layer forming step S3, the adhesive G is supplied to the center in the radial direction of the first surface 21. When the mount unit 72 is rotated around the rotation axis R by the drive unit which is not illustrated in a state in which the adhesive G is supplied onto the first surface 21 of the wafer 20, the adhesive G spreads outward in the radial direction due to a centrifugal force, and the adhesive layer 40 with a substantially uniform thickness is formed on the first surface 21. An adhesive G other than the adhesive G forming the adhesive layer 40 out of the adhesive G supplied onto the first surface 21 flies outward in the radial direction from the wafer 20 and gathers in the accommodation unit 71. The adhesive G gathering in the accommodation unit 71 is sent to the nozzle unit 73 by the recovery unit 74 and may be reused as an adhesive G to be supplied from the nozzle unit 73 or may not be sent to the nozzle unit 73 but be discharged as a waste.

As described above, the adhesive layer 40 illustrated in FIG. 8 can be formed using the spin coater 70. The adhesive layer 40 includes an adhesive body 41 covering the circuit part 11 on the first surface 21, an attached part 42 attached to the first trimmed part 31, and a filling part 43 located in the second trimmed part 32. The attached part 42 is attached to, for example, an inner part in the radial direction of the side surface 31b and the bottom surface 31a. The filling part 43 fills, for example, the whole second trimmed part 32. The filling part 43 may fill only a part in the second trimmed part 32.

As illustrated in FIG. 9, the support member fixing step S4 is a step of fixing the wafer 20 to a support member 50 via the adhesive layer 40. A material of the support member 50 may be silicon, metal, or an organic material. The support member 50 may be a transparent member. When the support member 50 is a transparent member, the support member 50 is, for example, a glass substrate. A release layer (not illustrated) is formed on one surface of the support member 50. The release layer may be formed on the whole surface of the support member 50, and an end portion thereof may be removed by partial etching or the like. The release layer is a layer that absorbs light. The release layer is formed on the support member 50, for example, using a spin coating method. In the support member fixing step S4, the wafer 20 is fixed to the surface of the support member 50 on which the release layer is formed via the adhesive layer 40.

The grinding step S5 is a step of decreasing the dimension in the thickness direction Z of the wafer 20 by grinding the wafer 20 from the second surface 22 side. As illustrated in FIG. 10, the dimension T in the thickness direction Z of the wafer 20 becomes equal to the dimension Tw in the thickness direction Z of the substrate part 10 in the semiconductor device 100 through the grinding step S5. The bottom surface 31a of the first trimmed part 31 and the groove bottom surface 32a of the second trimmed part 32 are ground and removed through the grinding step S5.

As illustrated in FIG. 11, the metal film forming step S6 is a step of forming a metal film 60 on the second surface 22a of the wafer 20 which has been ground. A material of the metal film 60 is, for example, titanium (Ti), Nickel (Ni), gold (Au), silver (Ag), is copper (Cu). The metal film 60 is formed, for example, using sputtering. The metal film 60 may be formed on only the second surface 22a of the wafer 20 as illustrated in FIG. 11, but may be formed on an end of the support member 50. The metal film 12 of the semiconductor device 100 is formed by a part of the metal film 60.

The support member removing step S7 is a step of removing the support member 50. The support member removing step S7 may be performed in any way as long as the support member 50 can be removed. For example, when the support member 50 is a transparent member, the release layer which is not illustrated in the support member 50 is irradiated with laser light from the surface opposite to the surface on which the release layer is formed such that the release layer absorbs the laser light and is heated in the support member removing step S7 according to the first embodiment, whereby an adhesive force between the release layer and the adhesive layer 40 is decreased. Accordingly, the support member 50 can be removed from the wafer 20. By removing the adhesive layer 40 attached to the wafer 20 using a tape or the like after removing the support member 50 from the wafer 20, the support member 50 and the adhesive layer 40 can be removed from the wafer 20. The adhesive layer 40 attached to the wafer 20 may be removed using an organic solvent.

The support member removing step S7 may be a step of removing the support member 50 from the wafer 20 by applying heat or an organic solvent to the adhesive layer 40 or may be step of removing the support member 50 from the wafer 20 by inserting a blade into an end of the adhesive layer 40 to form a start point and slowly raising the support member 50.

The dicing step S8 is a step of dicing the wafer 20 by cutting the wafer 20 along the dicing lines 24. By cutting the wafer 20 along the dicing lines 24, the dicing areas 23a are individually divided to form a plurality of semiconductor devices 100. Although not illustrated, the support member removing step S7 and the dicing step S8 are performed in a state in which the wafer 20 is supported by a dicing tape attached to the metal film 60.

As described above, the method of manufacturing the semiconductor device 100 according to the first embodiment includes forming a first trimmed part 31 by performing trimming of the wafer 20 from the first surface 21 side, forming a second trimmed part 32 by performing trimming of the wafer 20 from the first surface 21 side, forming an adhesive layer 40 on the first surface 21 using a spin coating method including rotating the wafer 20 around a rotation axis R, fixing the wafer 20 to a support member 50 via the adhesive layer 40, and grinding the wafer 20 from the second surface 22 side to decrease a dimension in the thickness direction Z of the wafer 20. The second trimmed part 32 includes a part which is located on an inner side with respect to the first trimmed part 31 in the radial direction from the rotation axis R. Accordingly, when the adhesive layer 40 is formed using the spin coating method, it is possible to trap a part of the adhesive G spreading outward in the radial direction due to a centrifugal force in the second trimmed part 32 and to decrease an amount of adhesive G flowing outward in the radial direction from the second trimmed part 32. Accordingly, it is possible to decrease an amount of adhesive G flowing from the second trimmed part 32 to the first trimmed part 31 in the adhesive layer forming step S3. Accordingly, it is possible to curb the adhesive G turning and flowing to the side surface 25 of the wafer 20 from the first trimmed part 31.

Specifically, for example, since a part of the adhesive G is trapped in the second trimmed part 32, it is possible to decrease an amount of adhesive G flowing from the second trimmed part 32 to the protruding part 33 in the adhesive layer forming step S3. At least a part of the adhesive G flowing onto the protruding part 33 flies outward in the radial direction from the wafer 20 from the outer circumferential edge of the protruding part 33 due to a centrifugal force and gathers in the accommodation unit 71. At this time, when the amount of adhesive G flowing on the protruding part 33 is large, some adhesive G is likely to flow to the first trimmed part 31 and the adhesive G is likely to turn and flow to the side surface 25 of the wafer 20 from the first trimmed part 31. On the other hand, according to the first embodiment, since the second trimmed part 32 is provided on the inner side in the radial direction of the first trimmed part 31, it is possible to decrease an amount of adhesive G flowing from the inner side in the radial direction to the protruding part 33. Accordingly, it is possible to decrease an amount of adhesive G flowing from the protruding part 33 to the first trimmed part 31 and to curb the adhesive G turning and flowing to the side surface 25 of the wafer 20.

Since the adhesive G can be prevented from turning and flowing to the side surface 25 of the wafer 20, it is possible to curb a tool for grinding the wafer 20 entraining the adhesive G even when the side surface 25 of the wafer 20 is ground at the time of grinding and thinning the wafer 20 in the grinding step S5. Accordingly, it is possible to curb the removed adhesive G serving as a waste in the grinding step S5 and to curb occurrence of a problem in that the removed adhesive G is attached to the wafer 20 and attached to a tool for performing the grinding step S5. As a result, it is possible to curb an increase in the number of steps for manufacturing the semiconductor device 100.

For example, by providing only the first trimmed part 31, it is possible to curb the adhesive G turning and flowing to the side surface 25 of the wafer 20 in comparison with a case in which the first trimmed part 31 is not provided. However, in order to sufficiently curb the adhesive G turning and flowing to the side surface 25 using the only the first trimmed part 31, the dimension D1 in the thickness direction Z of the first trimmed part 31 needs to be set to be sufficiently large. When the dimension D1 in the thickness direction Z of the first trimmed part 31 is set to be large, an amount of wear of the blade B used to form the first trimmed part 31 is likely to increase, and a frequency of replacement of the blade B is likely to increase. Accordingly, there is concern about an increase in manufacturing cost of the semiconductor device 100. A time taken to form the first trimmed part 31 using the blade B increases and a problem in that chipping is formed on the side surface 31b of the first trimmed part 31 which is ground by the blade B is likely to occur. On the other hand, according to the first embodiment, since the second trimmed part 32 is provided, it is possible to curb the adhesive G turning and flowing to the side surface 25 of the wafer 20 without increasing the dimension D1 in the thickness direction Z of the first trimmed part 31. Accordingly, it is possible to curb an increase in manufacturing cost of the semiconductor device 100 and to make it difficult to cause a problem such as chipping on the wafer 20.

According to the first embodiment, the first trimmed part 31 is formed all over the outer circumferential edge of the first surface 21. Accordingly, it is possible to curb the adhesive G turning and flowing to the side surface 25 of the wafer 20 in comparison with a case in which the first trimmed part 31 is formed in only a part of the outer circumferential edge of the first surface 21. Since the outer circumferential edge of the first surface 21 is trimmed all over the outer circumference, it is possible to curb the outer circumferential edge of the wafer 20 having an acute shape called a knife edge when the wafer 20 is thinned in the grinding step S5. Accordingly, it is possible to curb occurring of a defect such as cracking of the circuit part 11 due to cracking of the outer circumferential edge of the wafer 20 after the wafer 20 has been thinned in the grinding step S5.

For example, when only curbing the adhesive G turning and flowing to the side surface 25 of the wafer 20 in the adhesive layer forming step S3 is considered, a capacity of the second trimmed part 32 can be increased to increase an amount of adhesive G which can be trapped in the second trimmed part 32, and an amount of adhesive G flowing from the second trimmed part 32 to the first trimmed part 31 can be decreased. However, when an amount of adhesive G flowing to the first trimmed part 31 is excessively small or no adhesive G flows to the first trimmed part 31, the adhesive G may not be attached to the bottom surface 31a and the side surface 31b of the first trimmed part 31. When no adhesive G is attached to the bottom surface 31a and the side surface 31b of the first trimmed part 31, a stress may be concentrated on a part in which the bottom surface 31a and the side surface 31b are connected at the time of grinding the wafer 20 in the grinding step S5, and thus there is concern about cracking of the wafer 20 or the like.

On the other hand, according to the first embodiment, the dimension D2 in the thickness direction Z of the second trimmed part 32 is less than the dimension D1 in the thickness direction Z of the first trimmed part 31. Accordingly, it is possible to curb an excessive increase in capacity of the second trimmed part 32 and to curb an excessive increase in an amount of adhesive G trapped in the second trimmed part 32 in the adhesive layer forming step S3. As a result, it is possible to curb an excessive decrease in an amount of adhesive G flowing from the second trimmed part 32 to the first trimmed part 31 in the adhesive layer forming step S3. Accordingly, it is possible to allow a part of the adhesive G to appropriately flow to the first trimmed part 31 in the adhesive layer forming step S3 and to easily form the attached part 42 attached to the bottom surface 31a and the side surface 31b of the first trimmed part 31 as a part of the adhesive layer 40. As a result, it is possible to reinforce a connection part between the bottom surface 31a and the side surface 31b with the attached part 42 and to easily distribute a stress applied to the connection part between the bottom surface 31a and the side surface 31b in the grinding step S5 using the attached part 42. Accordingly, it is possible to curb cracking of the wafer 20 in the grinding step S5.

According to the first embodiment, the width W2 in the radial direction of the second trimmed part 32 is equal to or greater than the width W1 in the radial direction of the first trimmed part 31. Accordingly, it is possible to appropriately easily increase the width W2 in the radial direction of the second trimmed part 32 and to appropriately easily increase an amount of adhesive G which can be trapped in the second trimmed part 32. As a result, it is possible to appropriately decrease an amount of adhesive G flowing from the second trimmed part 32 to the first trimmed part 31 in the adhesive layer forming step S3 and to further curb the adhesive G turning and flowing to the side surface 25 of the wafer 20. Since the second trimmed part 32 can be formed using the same blade B as the blade B for forming the first trimmed part 31, a plurality of types of blades B with different widths in the radial direction do not need to be prepared.

Accordingly, it is possible to further decrease the manufacturing cost of the semiconductor device 100.

According to the first embodiment, the second trimmed part 32 is separated inward in the radial direction from the first trimmed part 31. Accordingly, the protruding part 33 can be provided between the first trimmed part 31 and the second trimmed part 32 in the radial direction. As a result, it is possible to easily stop the adhesive G which is going to flow outward in the radial direction from the second trimmed part 32 using the protruding part 33. It is also possible to prevent the adhesive G trapped in the second trimmed part 32 from leaking from the second trimmed part 32 in the adhesive layer forming step S3. Accordingly, it is possible to more appropriately decrease an amount of adhesive G flowing to the first trimmed part 31 and to more appropriately curb the adhesive G turning and flowing to the side surface 25 of the wafer 20.

According to the first embodiment, the width W3 in the radial direction of the part located between the first trimmed part 31 and the second trimmed part 32 in the radial direction, that is, the protruding part 33, is greater than both the dimension D1 in the thickness direction Z of the first trimmed part 31 and the dimension D2 in the thickness direction Z of the second trimmed part 32. Accordingly, it is possible to appropriately easily increase the width W3 in the radial direction of the protruding part 33. Since the width W3 in the radial direction of the protruding part 33 can be increased, the adhesive G flowing from the second trimmed part 32 to the protruding part 33 is less likely to flow to the first trimmed part 31 in the adhesive layer forming step S3. Accordingly, it is possible to appropriately facilitate flying of the adhesive G flowing to the protruding part 33 to the outer side in the radial direction of the side surface 25 of the wafer 20 from the outer edge in the radial direction of the protruding part 33 due to a centrifugal force. As a result, it is possible to further curb the adhesive G turning and flowing to the side surface 25 of the wafer 20. When the width W3 in the radial direction of the protruding part 33 is greater than at least one of the dimension D1 in the thickness direction Z of the first trimmed part 31 and the dimension D2 in the thickness direction Z of the second trimmed part 32, it is possible to further curb the adhesive G turning and flowing to the side surface 25 of the wafer 20 in the same way as described above.

According to the first embodiment, the second trimmed part 32 is a ring-shaped groove. Accordingly, in comparison with a case in which the second trimmed part 32 is provided in only a part in the circumferential direction around the rotation center R, it is possible to appropriately increase an amount of adhesive G which can be trapped in the second trimmed part 32. As a result, it is possible to further curb the adhesive G turning and flowing to the side surface 25 of the wafer 20.

The method of manufacturing the semiconductor device 100 according to the first embodiment further includes forming the adhesive layer 40 using the spin coating method using the spin coater 70. The spin coater 70 includes the mount unit 72 on which the wafer 20 is mounted and which is rotatable around the rotation axis R, the accommodation unit 71 in which the wafer 20 is accommodated, the nozzle unit 73 which supplies an adhesive G for forming the adhesive layer 40 onto the wafer 20, and the recovery unit 74 which recovers the adhesive G from the accommodation unit 71 to the nozzle unit 73. For example, even when the adhesive G turns and flows to the side surface 25 of the wafer 20 in the adhesive layer forming step S3, it is possible to curb generation of a waste of the adhesive G in the grinding step S5 by removing the adhesive G attached to the side surface 25 using a rinse liquid after forming the adhesive layer 40. However, when the spin coater 70 including the recovery unit 74 is used, the rinse liquid is mixed into a surplus adhesive G gathering in the accommodation unit 71 by removing a part of the adhesive layer 40 using the rinse liquid, and thus the adhesive G cannot be recovered and reused. Accordingly, when the adhesive layer 40 is formed using the spin coater 70 including the recovery unit 74, the adhesive G attached to the side surface 25 of the wafer 20 cannot be removed using the rinse liquid. On the other hand, according to the first embodiment, it is possible to curb the adhesive G turning and flowing to the side surface 25 of the wafer 20 without using the rinse liquid as described above. As a result, it is possible to reuse the adhesive G using the spin coater 70 including the recovery unit 74 and to decrease costs for forming the adhesive layer 40. Accordingly, it is possible to decrease the manufacturing cost of the semiconductor device 100.

For example, when the adhesive G is a material with a relatively high molecular weight, a rinse liquid that can melt and remove the adhesive G may not be known or it is difficult to prepare such a rinse liquid. According to the first embodiment, it is possible to curb the adhesive G turning and flowing to the side surface 25 of the wafer 20 without removing a part of the adhesive layer 40 using the rinse liquid as described above. Accordingly, it is possible to curb the adhesive G turning and flowing to the side surface 25 of the wafer 20 regardless of the type of the adhesive G.

### Second Embodiment

A second embodiment is different from the first embodiment in a shape of the second trimmed part. In the following description, the same constituents as in the aforementioned embodiment will be referred to by the same reference signs, and thus description thereof may be omitted.

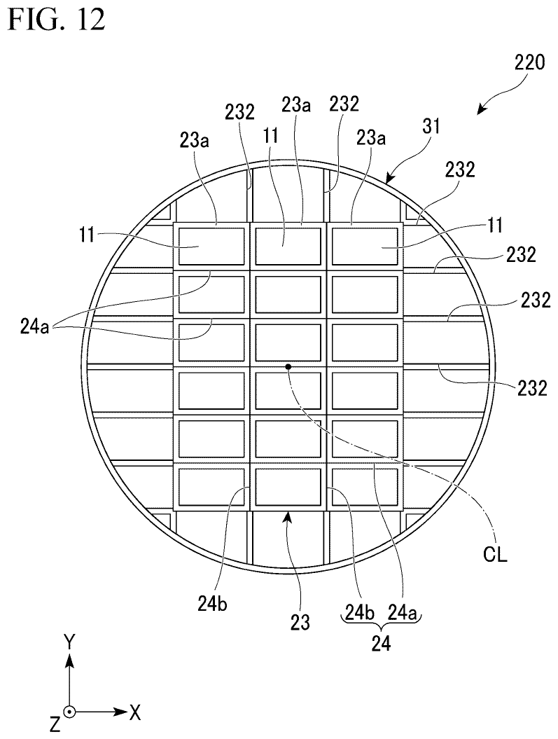

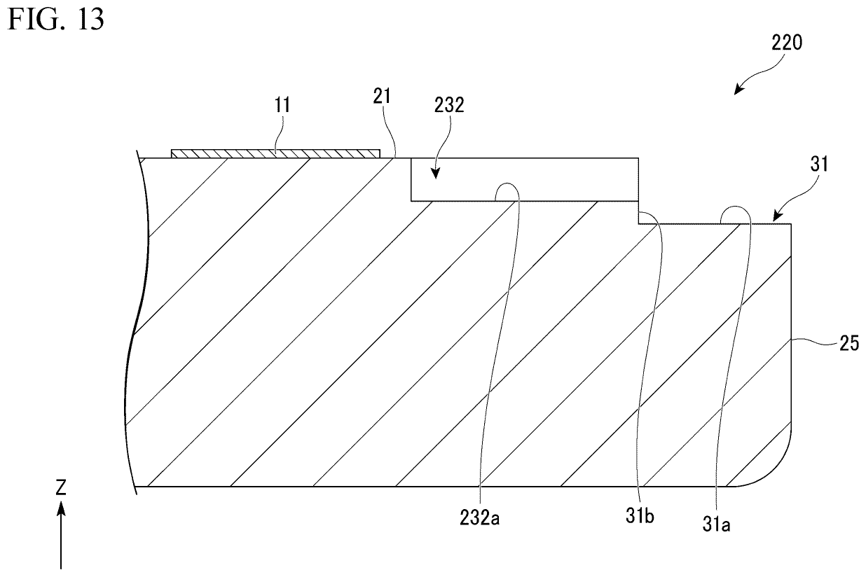

FIG. 12 is a plan view illustrating a wafer (substrate) 220 on which a first trimming step S1 and a second trimming step S2 according to the second embodiment have been performed. FIG. 13 is a sectional view illustrating a part of the wafer 220 on which the first trimming step S1 and the second trimming step S2 according to the second embodiment have been performed.

As illustrated in FIG. 12, a second trimmed part 232 in the second embodiment is a groove that is formed along parts located on the outer side in the radial direction with respect to device areas 23 in which the circuit part 11 is formed out of dicing lines 24 provided on the wafer 220. In the second embodiment, the second trimmed part 232 is formed in each of the parts located on the outer side in the radial direction with respect to the device areas 23 out of the dicing lines 24. In the second embodiment, the second trimmed part 232 includes a plurality of second trimmed parts 232 extending in the first direction X along the first dicing lines 24a and a plurality of second trimmed parts 232 extending in the second direction Y along the second dicing lines 24b. The second trimmed parts 232 are formed by pre-dicing the parts located on the outer side in the radial direction with respect to the device areas 23 out of the dicing lines 24.

As illustrated in FIG. 13, each second trimmed part 232 is connected to the inner side in the radial direction of the first trimmed part 31. An outer end in the radial direction of each second trimmed part 232 is open to the side surface 31b of the first trimmed part 31. A groove bottom surface 232a of the second trimmed part 232 is located on the first side (the +Z side) with respect to the bottom surface 31a of the first trimmed part 31.

In this specification, “a second trimmed part is connected to a first trimmed part” means that the second trimmed part is provided adjacent to the first trimmed part when seen in the thickness direction of the substrate. As illustrated in FIG. 12, each second trimmed part 232 in the second embodiment is adjacent to the inner side in the radial direction of the first trimmed part 31 when seen in the thickness direction Z.

In the second embodiment, for example, after a plurality of second trimmed parts 232 have been formed by pre-dicing, the first trimmed part 31 having a ring shape is formed. That is, unlike the first embodiment, the second trimming step S2 is performed earlier than the first trimming step S1. In the second embodiment, the second trimming step S2 may be performed later than the first trimming step S1. The other methods of the method of manufacturing the semiconductor device 100 according to the second embodiment are the same as the other methods of the method of manufacturing the semiconductor device 100 according to the first embodiment.

According to the second embodiment, the second trimmed parts 232 are connected to the first trimmed part 31. Accordingly, in comparison with a case in which the second trimmed parts 232 are formed to be separated inward in the radial direction from the first trimmed part 31, it is possible to further increase an area which can be used as the device area 23 in the wafer 220. As a result, it is possible to increase the number of semiconductor devices 100 which can be manufactured from one wafer 220. Since the second trimmed parts 232 are formed in a radial shape from the center of the wafer 220 to edges of the wafer 220 similarly to the forming direction of the adhesive layer 40 using the spin coating method, it is possible to curb void entrainment of the adhesive layer 40 and generation of voids in the support member fixing step S4.

According to the second embodiment, the second trimmed parts 232 are grooves that are formed along parts located on the outer side in the radial direction with respect to the device areas 23 in which the circuit part 11 is formed out of dicing lines 24 provided on the wafer 220. Accordingly, grooves which are formed by earlier performing some of operations of dicing the wafer 220 which are performed in the dicing step S8 can be used as the second trimmed parts 232. Accordingly, in comparison with a case in which a step of forming the second trimmed parts 232 is provided separately from dicing in the dicing step S8, it is possible to more easily decrease the number of steps for manufacturing the semiconductor device 100. Since pre-dicing is not performed on the device areas 23 and thus the dicing areas 23a are not divided in the grinding step S5, subsequent operations can be easily performed. Pre-dicing may be performed on the dicing lines 24 in the whole area of the wafer 220, and grooves formed by the pre-dicing may be used as the second trimmed parts 232. In this case, similarly, it is possible to decrease the number of steps for manufacturing the semiconductor device 100.

### Third Embodiment

A third embodiment is different from the first embodiment in a dimension in the thickness direction Z of the second trimmed part. In the following description, the same constituents as in the aforementioned embodiment will be referred to by the same reference signs, and thus description thereof may be omitted.

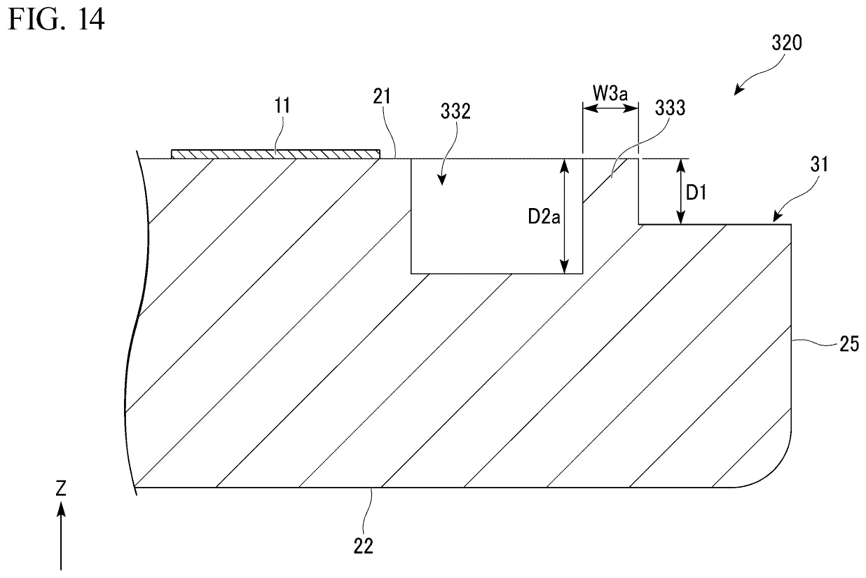

FIG. 14 is a sectional view illustrating a part of a wafer (substrate) 320 on which a first trimming step S1 and a second trimming step S2 according to the third embodiment have been performed. As illustrated in FIG. 14, a dimension D2a in the thickness direction Z of a second trimmed part 332 is greater than the dimension D1 in the thickness direction Z of the first trimmed part 31. In the third embodiment, a width W3a in the radial direction of a protruding part 333 which is a part located between the first trimmed part 31 and the second trimmed part 332 in the radial direction is less than the dimension D1 in the thickness direction Z of the first trimmed part 31 and the dimension D2a in the thickness direction Z of the second trimmed part 332. The other methods of the method of manufacturing the semiconductor device 100 according to the third embodiment are the same as the other methods of the method of manufacturing the semiconductor device 100 according to the first embodiment.

According to the third embodiment, the dimension D2a in the thickness direction Z of the second trimmed part 332 is greater than the dimension D1 in the thickness direction Z of the first trimmed part 31. Accordingly, it is possible to appropriately increase the dimension D2a in the thickness direction Z of the second trimmed part 332 and to appropriately increase an amount of adhesive G which can be trapped in the second trimmed part 332 in the adhesive layer forming step S3. As a result, it is possible to more appropriately decrease an amount of adhesive G flowing from the second trimmed part 332 to the first trimmed part 31 and to further curb the adhesive G turning and flowing to the side surface 25 of the wafer 320.

According to the third embodiment, the width W3a in the radial direction of the protruding part 333 which is a part located between the first trimmed part 31 and the second trimmed part 332 in the radial direction is less than the dimension D1 in the thickness direction Z of the first trimmed part 31 and the dimension D2a in the thickness direction Z of the second trimmed part 332. Accordingly, even when an amount of adhesive G trapped in the second trimmed part 332 is large in the adhesive layer forming step S3 and thus an amount of adhesive G flowing from the second trimmed part 332 to the protruding part 333 is small, it is possible to appropriately cause a part of the adhesive G flowing to the protruding part 333 to flow easily to the first trimmed part 31. As a result, it is possible to easily form the attached part 42 which is attached to the bottom surface 31a and the side surface 31b of the first trimmed part 31 as a whole. It is possible to curb cracking of the wafer 320 in the grinding step S5.

According to at least one of the aforementioned embodiments, the semiconductor device manufacturing method is a method of manufacturing a semiconductor device by machining a substrate (wafer) including a first surface on which a circuit part is provided and a second surface opposite to the first surface. The semiconductor device manufacturing method includes forming a first trimmed part by performing trimming of the substrate from the first surface side, forming a second trimmed part by performing trimming of the substrate from the first surface side, forming an adhesive layer on the first surface using a spin coating method including rotating the substrate around a rotation axis, fixing the substrate to a support member via the adhesive layer, and grinding the substrate from the second surface side to decrease a dimension in a thickness direction Z of the substrate. The second trimmed part includes a part which is located on an inner side with respect to the first trimmed part in a radial direction from the rotation axis. Accordingly, it is possible to curb the adhesive turning and flowing to the side surface of the substrate.

Forming the first trimmed part and forming the second trimmed part may be performed at any timings as long as the adhesive layer is not formed yet and may be performed in any order. For example, forming the first trimmed part and forming the second trimmed part may be performed in the same step. When forming the first trimmed part and forming the second trimmed part are performed in different steps, any step may be performed earlier. The shape of the first trimmed part and the shape of the second trimmed part are not particularly limited. The second trimmed part may include a part which is located at the same position in the radial direction as the first trimmed part as long as it includes a part located on the inner side in the radial direction of the first trimmed part.

The dimension in the thickness direction Z of the second trimmed part may be equal to the dimension in the thickness direction Z of the first trimmed part. The width in the radial direction of the second trimmed part may be less than the width in the radial direction of the first trimmed part or may be equal to the width in the radial direction of the first trimmed part. The width in the radial direction of the part located between the first trimmed part and the second trimmed part in the radial direction is not particularly limited and may be greater than one of the dimension in the thickness direction Z of the first trimmed part and the dimension in the thickness direction Z of the second trimmed part and may be less than the other thereof. The material of the adhesive layer is not particularly limited as long as the support member can be fixed to the substrate. The semiconductor device may be a semiconductor device in which a metal film is not formed on the second surface.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device manufacturing method of manufacturing a semiconductor device by machining a substrate including a first surface on which a circuit part is provided and a second surface opposite to the first surface, the semiconductor device manufacturing method comprising:
forming a first trimmed part by performing trimming of the substrate from the first surface side;
forming a second trimmed part by performing trimming of the substrate from the first surface side;
forming an adhesive layer on the first surface using a spin coating method including rotating the substrate around a rotation axis;
fixing the substrate to a support member via the adhesive layer; and
grinding the substrate from the second surface side to decrease a dimension in a thickness direction of the substrate,
wherein the second trimmed part includes a part which is located on an inner side with respect to the first trimmed part in a radial direction from the rotation axis.

2. The semiconductor device manufacturing method according to claim 1, wherein the first trimmed part is formed all over an outer circumferential edge of the first surface.

3. The semiconductor device manufacturing method according to claim 1, wherein a dimension in the thickness direction of the second trimmed part is less than a dimension in the thickness direction of the first trimmed part.

4. The semiconductor device manufacturing method according to claim 1, wherein a dimension in the thickness direction of the second trimmed part is greater than a dimension in the thickness direction of the first trimmed part.

5. The semiconductor device manufacturing method according to claim 1, wherein a width in the radial direction of the second trimmed part is equal to or greater than a width in the radial direction of the first trimmed part.

6. The semiconductor device manufacturing method according to claim 1, wherein the second trimmed part is separated inward in the radial direction from the first trimmed part.

7. The semiconductor device manufacturing method according to claim 6, wherein a width in the radial direction of a part which is located between the first trimmed part and the second trimmed part in the radial direction is greater than at least one of a dimension in the thickness direction of the first trimmed part and a dimension in the thickness direction of the second trimmed part.

8. The semiconductor device manufacturing method according to claim 1, wherein the second trimmed part is connected to the first trimmed part.

9. The semiconductor device manufacturing method according to claim 1, wherein the second trimmed part is a ring-shaped groove.

10. The semiconductor device manufacturing method according to claim 1, wherein the second trimmed part is a groove which is formed along a part located on an outer side in the radial direction with respect to a device area on which the circuit part is formed out of dicing lines provided in the substrate.

11. The semiconductor device manufacturing method according to claim 1, further comprising forming the adhesive layer using the spin coating method using a spin coater,
wherein the spin coater includes:
a mount unit on which the substrate is mounted and which is rotatable around the rotation axis;
an accommodation unit in which the substrate is accommodated;
a nozzle unit which supplies an adhesive for forming the adhesive layer onto the substrate; and
a recovery unit which recovers the adhesive from the accommodation unit to the nozzle unit.
